(19) United States
(12) Patent Application Publication
(10) Pub. No.: US 2012/0001033 A1
(43) Pub. Date: Jan. 5, 2012

(54) EQUIPMENT MOUNTING APPARATUS AND METHOD

(76) Inventors: Gary P. Wilde, Taylorsville, UT (US); Bryan Billingsley, Riverton, UT (US); Matthew Sovic, Bountiful, UT (US); Dean Bond, South Jordon, UT (US); John Foster, Morgan, UT (US); Aaron Desmond, Salt Lake City, UT (US); Joshua Wilde, Salt Lake City, UT (US)

(21) Appl. No.: 12/977,056

(22) Filed: Dec. 22, 2010

Related U.S. Application Data
(60) Provisional application No. 61/284,708, filed on Dec. 24, 2009.

(51) Int. Cl. H05K 7/00; B23P 11/00; F16M 13/02

(52) U.S. Cl. 248/73; 29/428

(57) ABSTRACT

An apparatus and method for mounting electronic equipment onto a pole are disclosed.

### RELATED APPLICATIONS

This application claims priority to U.S. Provisional patent application 61/284,708 entitled “THREE CAMERA MOUNTING BRACKET FOR FOUR INCH ROUND POLE” and filed on 24 Dec. 2009 for Gary Wilde and Bryan Billingsley. The aforementioned application is hereby incorporated by reference.

### BACKGROUND OF THE INVENTION

1.Field of the Invention

The claimed invention relates to brackets for mounting equipment—particularly electronic equipment—to a pole.

2. Description of the Related Art

Currently available equipment mounting brackets for poles are difficult to use and limited in the amount of equipment they hold and the available orientations for directional equipment such as cameras and microphones. [Add other problems here.]

### BRIEF SUMMARY OF THE INVENTION

The present invention has been developed in response to the present state of the art, and in particular, in response to the problems and needs in the art that have not yet been fully solved by currently available equipment mounting apparatus and methods. Accordingly, the present invention has been developed to provide equipment mounting apparatus and methods that overcome shortcomings in the art.

As detailed below, an apparatus for mounting equipment on a pole may include an inner wall configured to conform to and partially encompass a pole, an outer wall with one or more mounting faces for mounting equipment thereto, a tubular strut connected to the inner wall and the outer wall, and wherein the inner wall and the outer wall each have an aperture for passing cables through the tubular strut.

Furthermore, a method for mounting equipment on a pole may include obtaining an equipment mounting apparatus (such as the apparatus summarized above) and passing cables through the tubular strut and through an aperture in the pole. Examples of additional embodiments and details of the apparatus and method for mounting equipment on a pole are described below.

It should be noted that references throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussion of the features and advantages, and similar language, throughout this specification may, but do not necessarily, refer to the same embodiment.

The described features, advantages, and characteristics of the invention may be combined in any suitable manner in one or more embodiments. One skilled in the relevant art will recognize that the invention may be practiced without one or more of the specific features or advantages of a particular embodiment. In other instances, additional features and advantages may be recognized in certain embodiments that may not be present in all embodiments of the invention.

These features and advantages will become more fully apparent from the following description and appended claims, or may be learned by the practice of the invention as set forth hereinafter.

### BRIEF DESCRIPTION OF THE DRAWINGS

In order that the advantages of the invention will be readily understood, a more particular description of the invention briefly described above will be rendered by reference to specific embodiments that are illustrated in the appended drawings. Understanding that these drawings depict only typical embodiments of the invention and are not therefore to be considered to be limiting of its scope, the invention will be described and explained with additional specificity and detail through the use of the accompanying drawings, in which:

FIGS. 1 and 2 are respective front view and top view diagrams depicting a hexagonal mounting bracket for a round pole that is consistent with one or more embodiments of the claimed invention;

FIGS. 3 and 4 are top view diagrams further depicting the hexagonal mounting bracket for a round pole shown in FIGS. 1 and 2;

FIGS. 5 and 6 are respective front view and top view diagrams depicting a hexagonal mounting bracket for a square pole that is consistent with one or more embodiments of the claimed invention;

FIGS. 7 and 8 are top view diagrams further depicting the hexagonal mounting bracket for a square pole shown in FIGS. 5 and 6;

FIGS. 9 and 10 are respective front view and top view diagrams depicting a rectangular mounting bracket for a round pole that is consistent with one or more embodiments of the claimed invention;

FIGS. 11 and 12 are top view diagrams further depicting the rectangular mounting bracket for a round pole shown in FIGS. 9 and 10;

FIGS. 13 and 14 are respective front view and top view diagrams depicting a rectangular mounting bracket for a square pole that is consistent with one or more embodiments of the claimed invention;

FIGS. 15 and 16 are top view diagrams further depicting the rectangular mounting bracket for a square pole shown in FIGS. 13 and 14;

FIG. 17 is a flow chart diagram depicting a mounting bracket installation method that is consistent with one or more embodiments of the claimed invention; and

FIG. 18 depicts an equipment mounting system with two mounting brackets clamped to a round pole and electronic equipment mounted on multiple mounting faces of each mounting bracket.

### DETAILED DESCRIPTION OF THE INVENTION

Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of components and materials to provide a thorough understanding of embodiments of the invention. One skilled in the relevant art will recognize, however, that the invention may be practiced without one or more of the specific details, or with other methods, components, materials, and so forth. In other instances, well-known structures, materials, or operations are not shown or described in detail to avoid obscuring certain aspects of the invention.

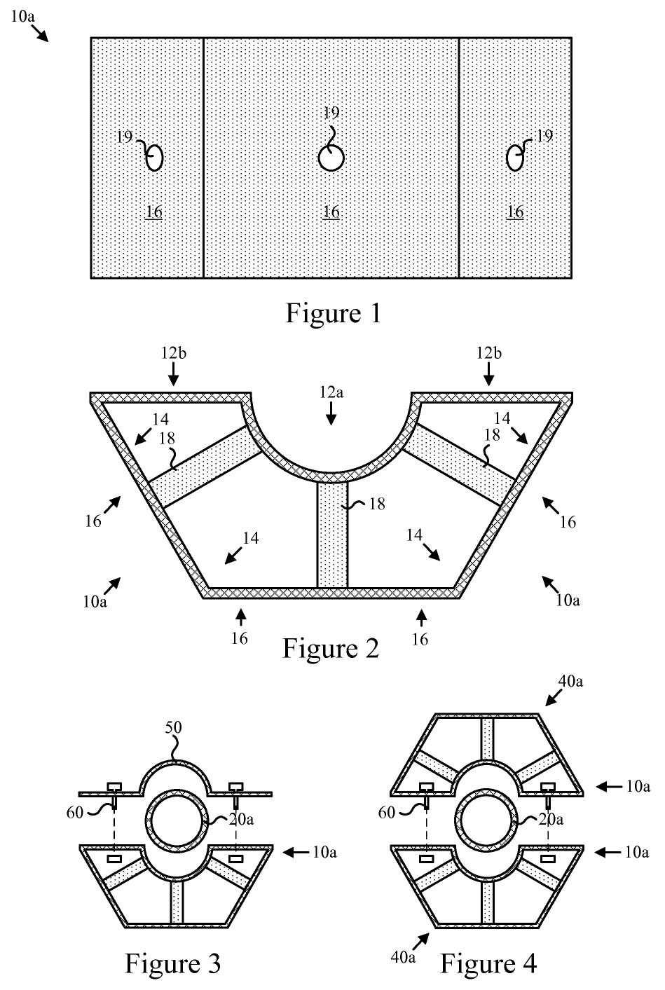

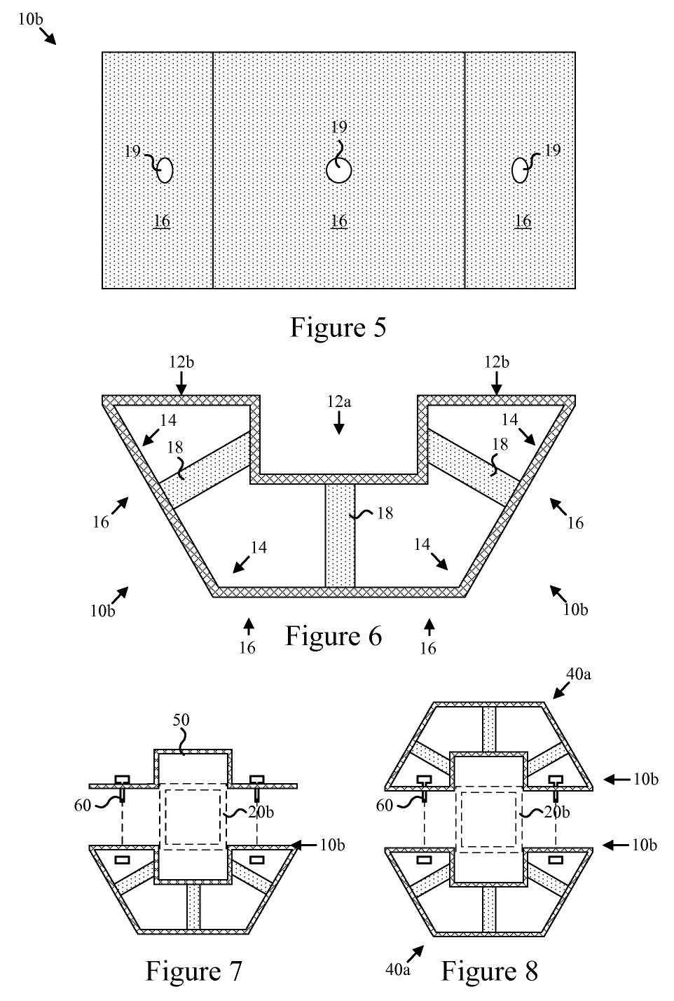

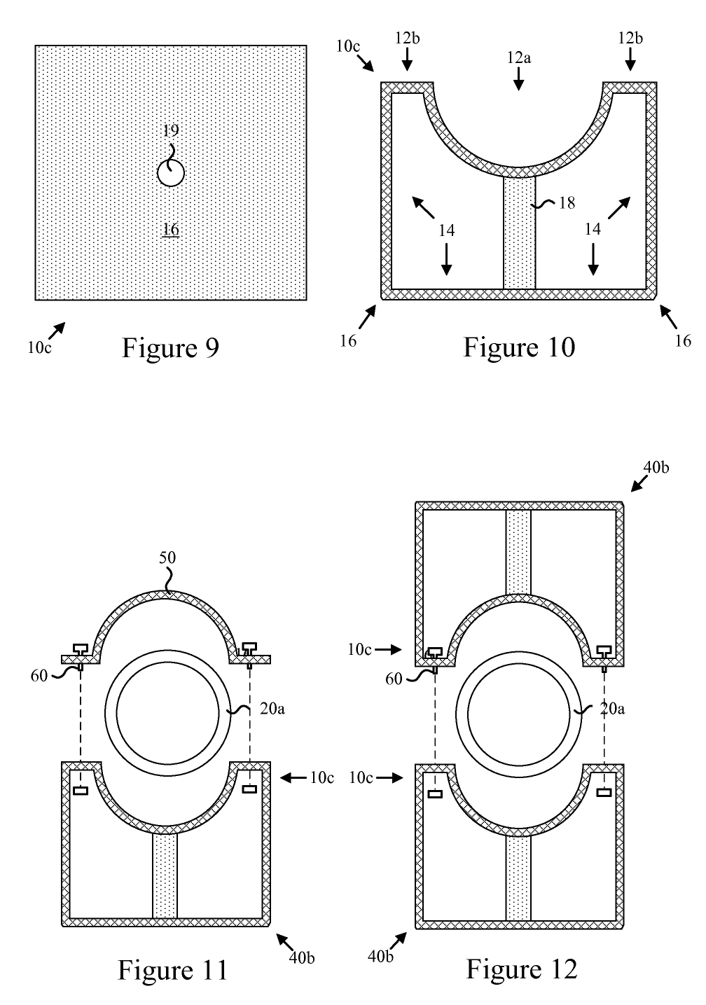

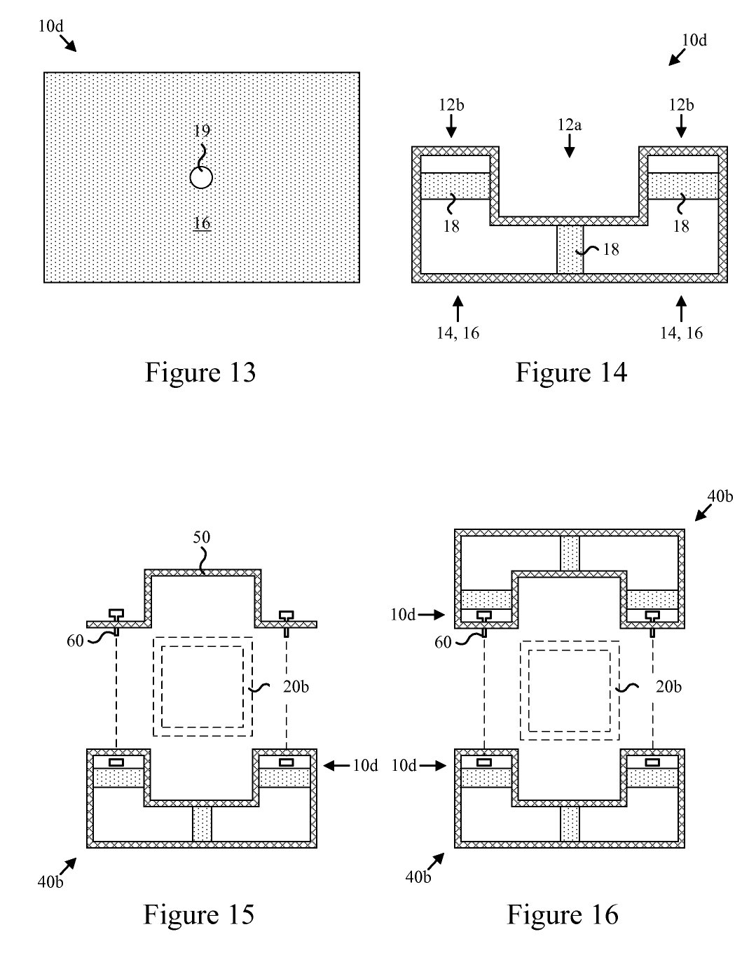

FIGS. 1-16 depict various embodiments of a mounting bracket 10 are that are consistent with the claimed invention. FIGS. 1-4 depict a hexagonal mounting bracket 10a for a round pole 20a while FIGS. 5-8 depicting a hexagonal mounting bracket 10b for a square pole 20b. Similarly, FIGS. 9-12 depict a rectangular mounting bracket 10c for the round pole 20a and FIGS. 13-16 depicting a rectangular mounting bracket 10d for the square pole 20b.

Each of the depicted embodiments of the mounting bracket 10 include an inner wall 12 configured to conform to and partially encompass a pole 20 and an outer wall 14 comprising one or more mounting faces 16 for mounting equipment thereto. Each mounting bracket 10 may also include one or more tubular struts 18 connected to the inner wall 12 and the outer wall 14. One or more apertures 19 may be formed into the inner wall 12 and outer wall 14 that facilitate passing cables through the tubular strut 18 and into the pole 20.

The pole 20 may have any useful or arbitrary cross-sectional shape such as round (FIGS. 3-4 and 11-12), elliptical, triangular, square (FIGS. 7-8 and 15-16), rectangular and hexagonal. Similarly, the tubular struct 18 may have any useful or arbitrary cross-sectional shape such as round, triangular, rectangular, hexagonal, or the like.

The mounting faces 16 may form a polygonal perimeter 40 such that each face is oriented in a different direction. For example, FIGS. 1-8 depict mounting brackets 10a and 10b having a semi-hexagonal perimeter 40a with mounting faces 16 at angular intervals of approximately 60 degrees. FIGS. 9-16 depict mounting brackets 10c and 10d having a semi-rectangular perimeter 40b with full or partial mounting faces 16 at angular intervals of approximately 90 degrees. Some mounting brackets 10 such as mounting brackets 10c and 10d depicted in FIGS. 9-16 may be mated with a similar mounting bracket such that two mounting faces 16 are coplanar and form a shared mounting face 16.

The inner wall 12 may include a pole mating portion 12a for conforming to and partially encompassing a pole. The pole mating portion 12a may be connected to one or more bracket mating faces 12b. The bracket mating faces 12b may be connected to mating faces of a paired bracket. The paired bracket may be an equipment mounting bracket 10 with mounting faces 16 (as demonstrated in FIGS. 4, 8, 12, and 16) or a plain bracket 50 without mounting faces (as demonstrated in FIGS. 3, 7, 11, and 15). Fasteners 60 may be used for mating the bracket mating faces 12b to the bracket mating faces 12b of the paired bracket.

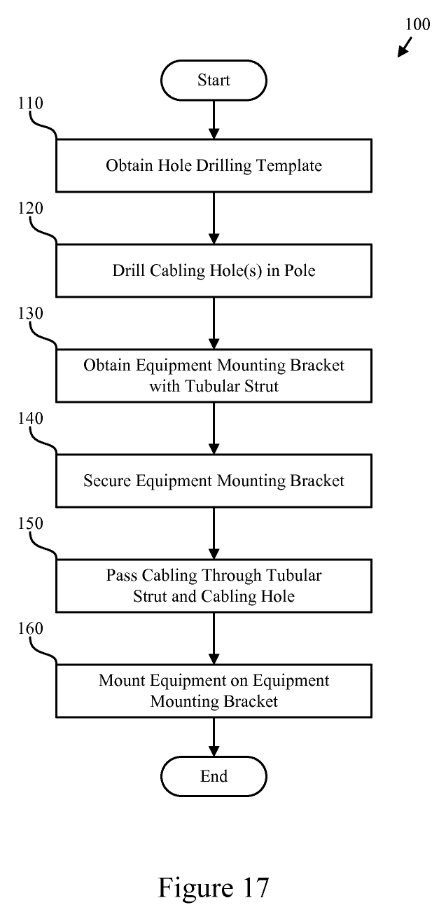

FIG. 17 is a flow chart diagram depicting a mounting bracket installation method 100 that is consistent with one or more embodiments of the claimed invention. As depicted, the method 100 includes obtaining 110 a hole drilling template, drilling 120 one or more cabling holes in a pole, obtaining 130 an equipment mounting bracket, securing 140 the equipment mounting bracket, passing 150 cabling through a tubular strut and a cabling hole, and mounting 160 equipment on the equipment mounting bracket. The mounting bracket installation method 100 may be performed in conjunction with the equipment mounting bracket 10 or the like.

Obtaining 110 may include obtaining a template for a particular bracket and pole size that facilitates marking particular points on the pole for drilling mounting cabling holes and other useful holes such as holes for fasteners. Drilling 120 one or more cabling holes in a pole may include drilling at the points indicated by the template. Obtaining 130 an equipment mounting bracket may include obtaining a mounting bracket 10 that is appropriate for a pole.

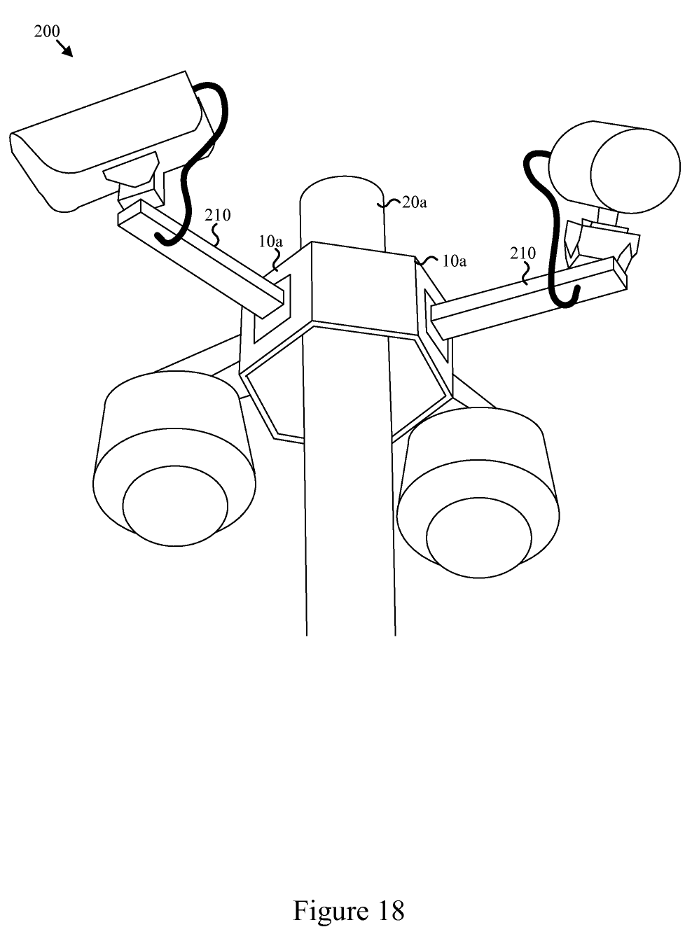

Securing 140 the equipment mounting bracket may include securing the bracket 10 to the pole 20 with one or more fasteners 60. Passing 150 may include passing electronic cables through a tubular strut 18 via an aperture 19 in a mounting face 16 and then through a cabling hole (not shown) in the pole. Mounting 160 may include mounting electronic equipment directly to the mounting face 16. Alternately, mounting 160 may include first mounting an extension arm to the mounting face 16 and attaching the equipment to the extension arm. Is such situations, the passing task 150 may include passing the electronic cables through the extension arm (See FIG. 18) either before or after the extension arm is mounted to the mounting face 16.

FIG. 18 depicts an equipment mounting system 200 with two mounting brackets 10a attached to a round pole 20a. Each mounting face 16 on the mounting brackets 10 may support electronic equipment with cables that pass through the apertures 19 (not shown) and the tubular struts 18 (not shown) and into the pole 20 thereby providing a secure mounting mechanism for the electronic equipment that also provides environmental protection to the electronic cables. An extension arm 210 is used on some the mounting faces to offset the equipment farther from the pole 20.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An apparatus for mounting equipment on a pole, the apparatus comprising:
an inner wall configured to conform to and partially encompass a pole;
an outer wall comprising one or more mounting faces for mounting equipment thereto;
a tubular strut connected to the inner wall and the outer wall; and
wherein the inner wall and the outer wall each comprise an aperture for passing cables through the tubular strut.

2. The apparatus of claim 1, further comprising an aperture in the pole for passing the cables into the pole.

3. The apparatus of claim 1, wherein the mounting faces form a perimeter that is substantially semi-hexagonal.

4. The apparatus of claim 1, wherein the mounting faces form a perimeter that is substantially semi-rectangular.

5. The apparatus of claim 1, wherein the inner wall comprises a first and a second bracket mating face.

6. The apparatus of claim 5, the inner wall further comprising a pole mating portion for conforming to and partially encompassing a pole, the pole mating portion connected to the first mating face and the second mating face.

7. The apparatus of claim 5, further comprising a plurality of fasteners for mating the first and the second bracket mating face to a first and a second bracket mating face of a second apparatus.

8. The apparatus of claim 7, wherein the second apparatus is an equipment mounting apparatus.

9. The apparatus of claim 7, wherein the second apparatus comprises a pole conforming portion configured to conform to and partially encompass a pole.

10. The apparatus of claim 1, wherein the tubular strut has a cross-sectional shape selected from the group consisting of round, triangular, rectangular, square and polygonal.

11. The apparatus of claim 1, wherein the tubular strut is substantially perpendicular to the inner wall and the outer wall.

12. The apparatus of claim 1, wherein the pole mating portion is shaped to conform to a pole having a cross-sectional shape that is selected from the group consisting of round, triangular, rectangular, square and polygonal.

13. A method for mounting equipment on a pole, the method comprising:
obtaining an equipment mounting apparatus comprising an inner wall configured to conform to and partially encompass a pole, an outer wall comprising one or more mounting faces for mounting equipment thereto, a tubular strut connected to the inner wall and the outer wall, wherein the inner wall and the outer wall each comprise an aperture for passing cables through the tubular strut; and
passing cables through the tubular strut and through an aperture in the pole.

14. The method of claim 13, wherein the pole mating portion is shaped to conform to a pole having a cross-sectional shape that is selected from the group consisting of round, triangular, rectangular, square and polygonal.

15. The method of claim 13, further comprising obtaining a hole drilling template.

16. The method of claim 13, further comprising forming the aperture in the pole.

17. The method of claim 13, further comprising mounting equipment on a mounting face of the one or more mounting faces.

18. The method of claim 13, further comprising fastening a first and a second bracket mating face of the inner wall to a first and a second bracket mating face of a second apparatus.

19. The method of claim 18, wherein the second apparatus is an equipment mounting apparatus.

20. The method of claim 18, wherein the second apparatus comprises a pole conforming portion configured to conform to and partially encompass a pole
